(19) United States
(12) Patent Application Publication
(10) Pub. No.: US 2012/0139107 A1
(43) Pub. Date: Jun. 7, 2012

(54) SEMICONDUCTOR CHIP AND SEMICONDUCTOR DEVICE USING THE CHIP

(75) Inventor: SUMIAKI NAKANO, Nara (JP)

(73) Assignee: PANASONIC CORPORATION, Osaka (JP)

(21) Appl. No.: 13/396,840

(22) Filed: Feb. 15, 2012

Related U.S. Application Data
(63) Continuation of application No. PCT/JP2010/001169, filed on Feb. 23, 2010.

(30) Foreign Application Priority Data
Aug. 19, 2009 (JP) 2009-190385

(51) Int. Cl. H01L 23/48

(52) U.S. Cl. 257/737; 257/E23.079

(57) ABSTRACT

A semiconductor chip includes at least one electrode pad formed on a substrate; a protective film formed on the substrate and the electrode pad, and having an opening exposing the electrode pad; an under barrier metal layer formed on the electrode pad to cover an edge of the opening of the protective film; and a bump formed on the under barrier metal layer. A contact angle between the under barrier metal layer and the protective film is less than 90° at an edge of the under barrier metal layer. A contact angle between the bump and the under barrier metal layer is less than 90° at an edge of the bump.

### CROSS-REFERENCE TO RELATED APPLICATIONS

This is a continuation of PCT International Application PCT/JP2010/001169 filed on Feb. 23, 2010, which claims priority to Japanese Patent Application No. 2009-190385 filed on Aug. 19, 2009. The disclosures of these applications including the specifications, the drawings, and the claims are hereby incorporated by reference in their entirety.

### BACKGROUND

The present disclosure relates to semiconductor chips and semiconductor devices using the chips; and more particularly to semiconductor chips including under barrier metal layers and bumps, and semiconductor devices using the chips.

In the field of a packaging technology of semiconductor devices, the technique of forming bump electrodes, such as chip size package (CSP) and flip-chip, on a substrate are used. In general, a bump electrode includes a passivation film, an under barrier metal (UBM) layer to which a bump is bonded, and a protective film for protecting the outermost surface of a substrate. Representative methods of forming a bump on a UBM layer are printing, plating, mounting of a bump material, etc. It is important to improve bond strength between a UBM layer and its underlying film, and between a bump and its underlying film to improve the reliability of a semiconductor device.

For example, Japanese Patent Publication No. 2006-19550 etc. suggests a bump electrode having a structure mitigating removal of UBM and the reduction in reliability of a bump caused by the removal.

In a conventional bump electrode, a first insulating film having a first opening and made of an inorganic material, and a second insulating film having a second opening in a position corresponding to the first opening and made of an organic material are sequentially formed on a substrate. A UBM layer is formed on the substrate in the first opening and the second opening. The UBM layer reaches the top of the first insulating film, and the peripheral edge of the UBM layer is located on the second insulating film. A bump is formed on the UBM layer. Each of the inner edge of the first insulating film defining the first opening and the inner edge of the second insulating film defining the second opening has a slope. The inner edge of the first insulating film defining the first opening is inclined at an angle of 45° or less. This configuration reduces the problems such as partial reduction in the thickness of the UBM layer and damages in the UBM layer at a step thereby providing higher reliability of a semiconductor device including a bump.

### SUMMARY

The conventional art suggests improving the bond reliability of the bump by reducing damages in the UBM layer from the inside but fails to suggest any means for reducing damages from the edges of the UBM layer and the bump. The advantages are thus limited and it is difficult to obtain a highly reliable semiconductor chip from the conventional art.

In view of the problems, it is an objective of the present disclosure to obtain a highly reliable semiconductor chip by improving the bond strength at the entire interface of the bump, the UBM layer, etc., and a semiconductor device using the chip.

In order to achieve the objective, the present disclosure provides a semiconductor chip in which the contact angle between an under barrier metal layer and a protective film is less than 90° at the edge of the under barrier metal layer.

Specifically, a semiconductor chip according to the first aspect includes at least one electrode pad formed on a substrate; a first protective film formed on the substrate and the electrode pad, and having a first opening exposing the electrode pad; an under barrier metal layer formed on the electrode pad to cover an edge of the first opening of the first protective film; and a bump formed on the under barrier metal layer. A contact angle between the under barrier metal layer and the first protective film is less than 90° at an edge of the under barrier metal layer. A contact angle between the bump and the under barrier metal layer is less than 90° at an edge of the bump.

In the semiconductor chip according to the first aspect, the contact angle between the under barrier metal layer and the first protective film is less than 90° at the edge of the under barrier metal layer. Also, the contact angle between the bump and the under barrier metal layer is less than 90° at the edge of the bump. This reduces concentration of stress applied between the under barrier metal layer and its underlying film, and between the bump and its underlying film, thereby reducing removal of the under barrier metal layer and the bump from their underlying films. Therefore, a highly reliable semiconductor chip can be obtained.

In the semiconductor chip according to the first aspect, the first opening of the first protective film preferably has a smaller size than the electrode pad.

This configuration reduces removal of the films such as the electrode pad and the protective film from the semiconductor chip.

The semiconductor chip according to the first aspect may further include a second protective film formed on the first protective film, and having a second opening in a position corresponding to the first opening of the first protective film.

A semiconductor chip according to a second aspect includes at least one electrode pad formed on a substrate; a first protective film formed on the substrate and the electrode pad, and having a first opening exposing the electrode pad; a second protective film formed on the first protective film, and having a second opening in a position corresponding to the first opening of the first protective film; an under barrier metal layer formed on the electrode pad to cover an edge of the first opening of the first protective film and an edge of the second opening of the second protective film; and a bump formed on the under barrier metal layer. A contact angle between the under barrier metal layer and the second protective film is less than 90° at an edge of the under barrier metal layer. A contact angle between the bump and the under barrier metal layer is less than 90° at an edge of the bump.

In the semiconductor chip according to the second aspect, the contact angle between the under barrier metal layer and the second protective film is less than 90° at the edge of the under barrier metal layer. The contact angle between the bump and the under barrier metal layer is less than 90° at the edge of the bump. This reduces concentration of stress applied between the under barrier metal layer and its underlying film, and between the bump and its underlying film, thereby reducing removal of the under barrier metal layer and the bump from their underlying films. Therefore, a highly reliable semiconductor chip can be obtained.

In the semiconductor chips according to the first and second aspects, the second opening of the second protective film preferably has a smaller size than the electrode pad.

This configuration reduces removal of the films such as the electrode pad and the protective film from the semiconductor chip.

In the semiconductor chips according to the first and second aspects, the second protective film is preferably made of polyimide.

This configuration increases the advantage of reducing removal of the layers such as the electrode pad, the under barrier metal layer, and the bump from the semiconductor chip.

In the semiconductor chips according to the first and second aspects, the first protective film is preferably made of silicon nitride.

This configuration increases the advantage of reducing removal of the layers such as the electrode pad, the under barrier metal layer, and the bump from the semiconductor chip.

In the semiconductor chips according to the first and second aspects, the bump preferably has a circular shape when viewed from above.

This configuration reduces stress concentration at one point as compared to a bump having a corner, e.g., a square shape etc. when viewed from above, thereby increasing the advantage of reducing removal of the bump etc. from the semiconductor chip.

In the semiconductor chips according to the first and second aspects, the under barrier metal layer preferably has a circular shape when viewed from above.

This configuration reduces stress concentration at one point as compared to a barrier metal film having a corner, e.g., a square shape etc. when viewed from above, thereby increasing the advantage of reducing removal of the under barrier metal layer etc. from the semiconductor chip.

In the semiconductor chips according to the first and second aspects, multiple ones of the at least electrode pad are preferably arranged in a grid pattern.

With this configuration, a large number of bumps can be arranged with small pitches.

A semiconductor device according to the present disclosure includes the semiconductor chip of the first or second aspect, and a mounting board on which the semiconductor chip is flip-chip mounted.

In the semiconductor device according to the present disclosure, the semiconductor chip of the first or second aspect is flip-chip mounted to provide a bump corresponding to a mounting type with increasing density, thereby obtaining a highly reliable semiconductor device.

In the semiconductor chip and the semiconductor device using the chip according to the present disclosure, the bond strength between the under barrier metal layer and its underlying film, and between the bump and its underlying film can be improved, thereby obtaining a highly reliable semiconductor chip and a semiconductor device using the chip.

### BRIEF DESCRIPTION OF THE DRAWINGS

FIG. 1A is a top view illustrating a semiconductor chip according to an example embodiment of the present disclosure.

FIG. 1B is a cross-sectional view illustrating the semiconductor chip according to the example embodiment.

FIGS. 2A and 2B are cross-sectional views illustrating detailed structures around an edge of an under barrier metal layer in the semiconductor chip according to the example embodiment.

FIG. 3 is a cross-sectional view illustrating a detailed structure around an edge of the under barrier metal layer in a semiconductor chip according to a first variation of the example embodiment.

FIG. 4 is a top view illustrating a semiconductor chip according to a second variation of the example embodiment.

FIG. 5 is a cross-sectional view illustrating a semiconductor device according to an example embodiment of the present disclosure.

### DETAILED DESCRIPTION

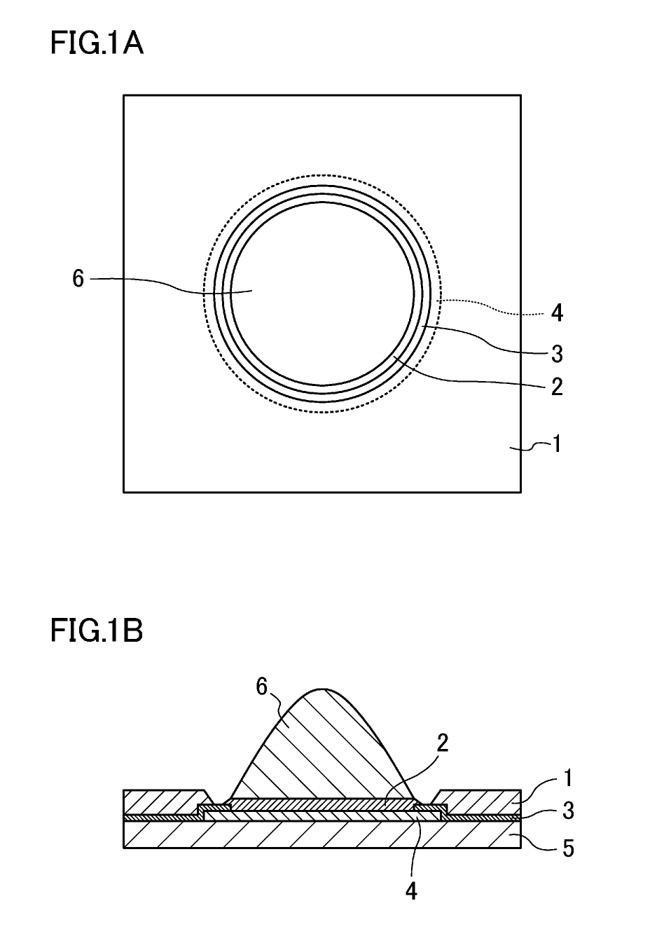

A semiconductor chip according to an example embodiment will be described below with reference to FIGS. 1-4.

As shown in FIGS. 1A and 1B, in the semiconductor chip according to this example embodiment, an electrode pad 4 is formed on a semiconductor substrate 5. A first protective film 3 made of, for example, silicon nitride (Si₃N₄) is formed to cover the semiconductor substrate 5 and the edge of the electrode pad 4. The first protective film 3 has an opening exposing the electrode pad 4. A second protective film 1 made of, for example, polyimide is formed on the first protective film 3. The second protective film 1 has an opening exposing the electrode pad 4. An under barrier metal layer (UBM) 2 is formed on the electrode pad 4 to cover the edge of the opening of the first protective film 3. A bump 6 is formed on the UBM layer 2.

The contact angle between the UBM layer 2 and the first protective film 3 is less than 90° at the edge of the UBM layer 2. The contact angle between the bump 6 and the UBM layer 2 is also less than 90° at the edge of the bump 6.

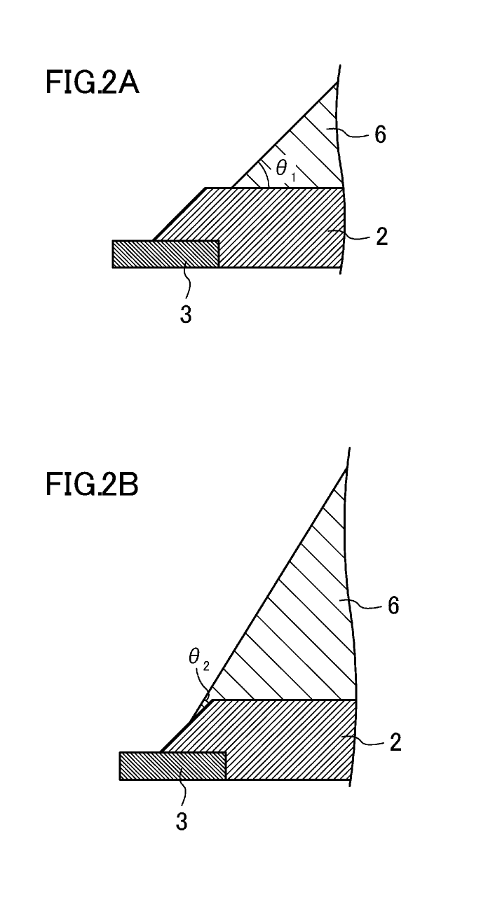

As shown in FIG. 2A, the contact angle between the bump 6 and the UBM layer 2, i.e., θ₁ in the figure, is preferably less than 90° at the edge of the bump 6, when the edge of the bump 6 is located on the upper surface of the UBM layer 2 which is parallel to the substrate structure of the UBM layer 2. On the other hand, as shown in FIG. 2B, when the edge of the bump 6 is located on a side surface of the UBM layer 2, θ₂ in the figure is preferably less than 90°. In this case, θ₂ is more preferably determined so that the sum of θ₂ and the contact angle between the first protective film 3 and the UBM layer 2 is less than 90°.

It is generally known that a phenomenon called a “notch effect,” which significantly reduces rupture strength and fatigue strength, occurs in a portion in which the cross-sectional shapes of the materials largely change. In the semiconductor chip according to this example embodiment, the UBM layer 2 and the bump 6 are formed so that the contact angle is less than 90°, thereby reducing concentration of stress applied between the UBM layer 2 and its underlying film, and between the bump 6 and its underlying film. This reduces removal of the UBM layer 2 and the bump 6 from their underlying films. The smaller the contact angle between the UBM layer 2 and the first protective film 3 around the UBM layer 2, and the contact angle between the bump 6 and the UBM layer 2 around the bump 6 are formed, the greater the advantage of reducing removal can be expected. Also, the second protective film 1 made of polyimide is formed on the first protective film 3 made of Si₃N₄, thereby increasing the effect of physical pressure. This further reduces removal of the layers such as the electrode pad 4 and the UBM layer 2 from the semiconductor chip.

While the second protective film 1 is formed in this example embodiment, the objective of the present disclosure may be achieved without forming the second protective film 1.

The opening of the second protective film 1, which is the outermost film, preferably has a smaller diameter than the electrode pad 4. This configuration increases strength of the structure around the bump 6. For example, even if the bond strength of the bump 6, the UBM layer 2, and the electrode pad 4 is relatively great, as long as a week film such as an extreme low-k (ELK) film is formed under them; the bump 6, the UBM layer 2, and the electrode pad 4 may be integrally removed from the semiconductor chip when stress is applied from longitudinal and lateral directions. In order to prevent this removal, the opening of the second protective film 1, which is the outermost film, is preferably formed so that the diameter is within the diameter of the electrode pad 4. Where the second protective film 1 is not formed, the opening of the first protective film 3 preferably has a smaller diameter than the electrode pad 4.

As shown in FIG. 1A, the bump 6 has preferably a circular shape when viewed from above. This configuration reduces stress concentration at one point as compared to the case where the bump 6 has a corner, e.g., a square shape etc. when viewed from above, thereby reducing removal of the bump 6 from the UBM layer 2.

Similarly, the UBM layer 2 also preferably has a circular shape when viewed from above. This configuration reduces stress concentration at one point as compared to the case where the UBM layer 2 has a corner, e.g., a square shape etc. when viewed from above, thereby reducing removal of the UBM layer 2 from the electrode pad 4 and the first protective film 3.

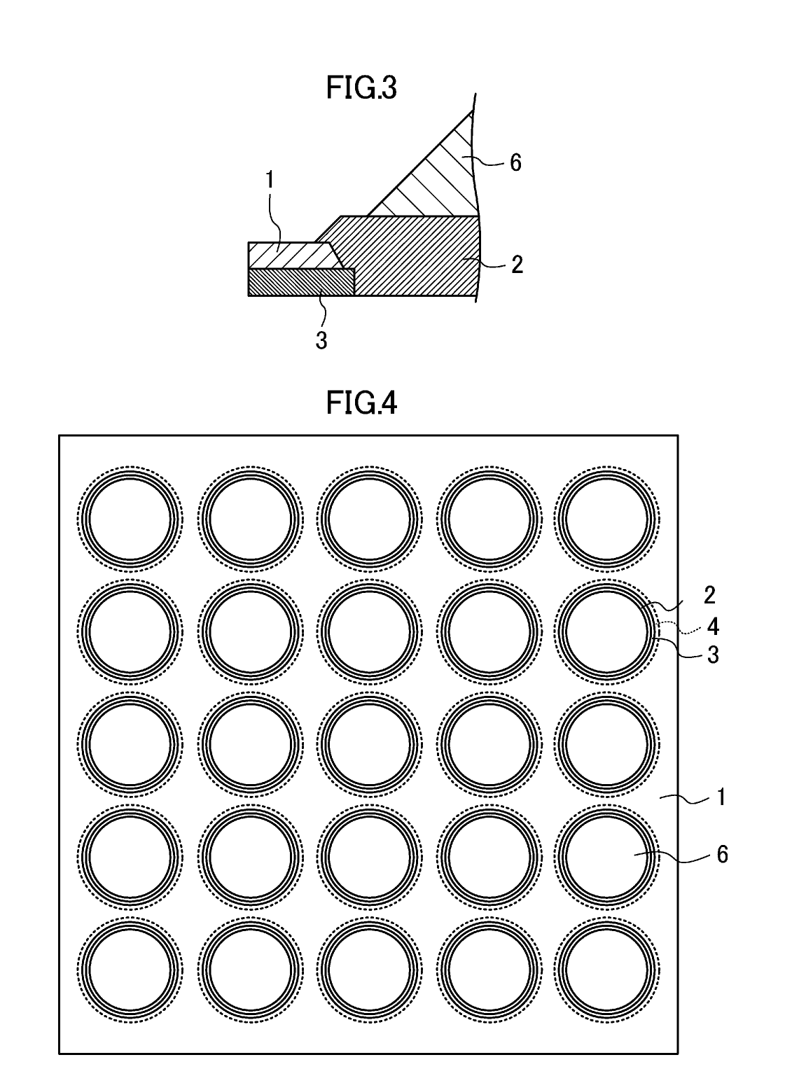

As shown in FIG. 3, the UBM layer 2 may be formed to cover not only the first protective film 3 but also the edge of the opening of the second protective film 1. Since this configuration improves adhesiveness of the UBM layer 2 to its underlying film (i.e., the second protective film 1), the advantage of reducing the removal of the UBM layer 2 from the electrode pad 4 and the first protective film 3 increases.

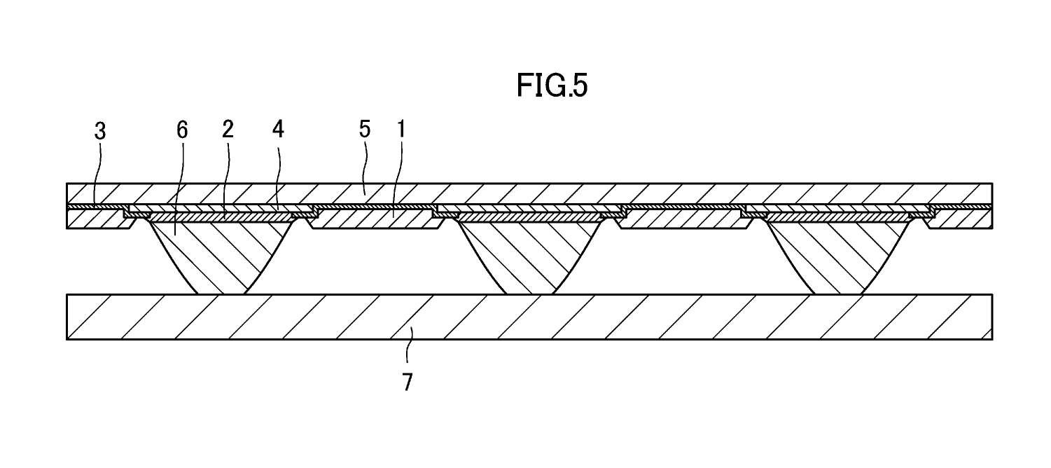

As shown in FIG. 4, multiple ones of the electrode pad 4 may be arranged on the semiconductor substrate 5 in a grid pattern. Each electrode pad 4 may be provided with the first protective film 3, the second protective film 1, the UBM layer 2, and the bump 6.

Next, a semiconductor device according to an example embodiment of the present disclosure will be described below with reference to FIG. 5.

The semiconductor device according to the example embodiment is formed by flip-chip mounting the semiconductor chip shown in FIG. 4 on a mounting board.

Specifically, as shown in FIG. 5, the semiconductor chip according to this example embodiment is provided on the upper surface of a mounting board 7 with the surface for bump formation facing downward. The mounting board 7 is bonded to the bump 6.

According to this example embodiment, a semiconductor device can be provided, which includes an applicable semiconductor chip corresponding to a mounting type with increasing density.

The semiconductor chip according to this example embodiment can be formed, for example, as follows.

The electrode pad 4 made of aluminum etc. is formed on the bump formation surface of the semiconductor substrate 5. The first protective film 3 made of Si₃N₄ etc. is formed to cover the bump formation surface of the semiconductor substrate 5 and the electrode pad 4. Then, the first protective film 3 selectively removed to form the opening exposing a part of the electrode pad 4.

Next, for example, polyimide is uniformly applied onto the electrode pad 4 and the first protective film 3 using a spinner. Then, prebake (for 50 seconds at a temperature of 70° C., for 50 seconds at a temperature of 90° C., and for 110 seconds at a temperature of 105° C.) is performed. After that, exposure is performed to form a pattern including an opening with a diameter nearly equal to that of the electrode pad 4. Then, pre-develop bake (for 50 seconds at a temperature of 80° C.), and development and curing (for 170 seconds at a temperature of 140° C., and for 3600 seconds at a temperature of 350° C.) are sequentially performed to form the second protective film 1 having the opening. Note that the second protective film 1 may be made of a benzoxazole or silicone resin material etc. instead of polyimide.

Then, the UBM layer 2 with a thickness ranging from about 1×10⁻³ mm to about 7×10⁻³ mm is formed in the opening, for example, as follows. After removing an oxide film by soft-etch of the surface of the electrode pad 4, the UBM layer 2 is immersed in zincate solution to deposit zinc particles, and is then immersed in electroless nickel (Ni) plating solution to form a Ni film with a thickness of about 5×10⁻³ mm on the electrode pad 4. Furthermore, it may be immersed in electroless gold (Au) solution to form flash Au plating with a thickness of about 5×10⁻³ mm on the Ni film.

Next, the bump 6 is formed on the UBM layer 2. The bump 6 can be formed by ball mounting, plating, dispensing, etc. For example, when ball mounting is employed, a printing mask is prepared, which is formed of a metal plate having a thickness ranging from about 0.02 mm to about 0.04 mm and an opening in the position corresponding to the UBM layer 2. After covering the entire bump formation surface of the semiconductor substrate 5 with the printing mask, a flux is printed on the surface of the UBM layer 2 using a squeegee made of rubber or metal. Then, a bump material is provided on the UBM layer 2, on which the flux is printed, using a mask for mounting having an opening in the position corresponding to the UBM layer 2. After that, the semiconductor substrate 5 provided with the bump material is subject to heat treatment to melt the bump material, thereby bonding the bump material to the UBM layer 2. In this process, the flux printed on the UBM layer 2 has both of two functions of holding the bump material and removing an oxide film at the time of remelting (reflow). Thus, the flux may be rosin or soluble flux etc. and is preferably halogen-free rosin flux. The bump is preferably a solder ball etc. made of a solder material such as tin, silver, copper, etc., but may be made of a material of other composition. With respect to the size of the bump material, the diameter preferably ranges from about 0.07 mm to about 0.125 mm. When the bump material is not in a spherical form, the average between the width of a longer side and the width of a shorter side preferably ranges from 0.07 mm to 0.125 mm. The material is however, not limited thereto. A material may be prepared with the amount needed so that the contact angle between the UBM layer 2 and the bump 6 formed on the UBM layer 2 is less than 90° at the edge of the bump 6 after the reflow.

The semiconductor chip and the semiconductor device using the chip according to the present disclosure improves the bond strength between the under barrier metal layer and its underlying film, and between the bump and its underlying film. Thus, a highly reliable semiconductor chip and a semiconductor device using the chip can be obtained. The present disclosure is particularly useful as a semiconductor chip including an under barrier metal layer and a bump and a semiconductor device etc. using the chip.

What is claimed is:

1. A semiconductor chip comprising:
at least one electrode pad formed on a substrate;
a first protective film formed on the substrate and the electrode pad, and having a first opening exposing the electrode pad;
an under barrier metal layer formed on the electrode pad to cover an edge of the first opening of the first protective film; and
a bump formed on the under barrier metal layer, wherein
a contact angle between the under barrier metal layer and the first protective film is less than 90° at an edge of the under barrier metal layer, and
a contact angle between the bump and the under barrier metal layer is less than 90° at an edge of the bump.

2. The semiconductor chip of claim 1, wherein
the first opening of the first protective film has a smaller size than the electrode pad.

3. The semiconductor chip of claim 1, further comprising
a second protective film formed on the first protective film, and having a second opening in a position corresponding to the first opening of the first protective film.

4. A semiconductor chip comprising:
at least one electrode pad formed on a substrate;
a first protective film formed on the substrate and the electrode pad, and having a first opening exposing the electrode pad;
a second protective film formed on the first protective film, and having a second opening in a position corresponding to the first opening of the first protective film;
an under barrier metal layer formed on the electrode pad to cover an edge of the first opening of the first protective film and an edge of the second opening of the second protective film; and
a bump formed on the under barrier metal layer, wherein
a contact angle between the under barrier metal layer and the second protective film is less than 90° at an edge of the under barrier metal layer, and
a contact angle between the bump and the under barrier metal layer is less than 90° at an edge of the bump.

5. The semiconductor chip of claim 3, wherein
the second opening of the second protective film has a smaller size than the electrode pad.

6. The semiconductor chip of claim 3, wherein
the second protective film is made of polyimide.

7. The semiconductor chip of claim 1, wherein
the first protective film is made of silicon nitride.

8. The semiconductor chip of claim 1, wherein
the bump has a circular shape when viewed from above.

9. The semiconductor chip of claim 1, wherein
the under barrier metal layer has a circular shape when viewed from above.

10. The semiconductor chip of claim 1, wherein
multiple ones of the at least one electrode pad are arranged in a grid pattern.

11. A semiconductor device comprising:
the semiconductor chip of claim 1; and
a mounting board on which the semiconductor chip is flip-chip mounted.
